(19) United States
(12) Patent Application Publication
(10) Pub. No.: US 2026/0308758 A1
(43) Pub. Date: Oct. 8, 2026

(54) HEAT MANAGEMENT SYSTEMS AND METHODS

(71) Applicant: ASM IP Holding B.V., Almere (NL)

(72) Inventors: Ran Li, Tempe, AZ (US); Hang Zhang, Tempe, AZ (US); Nirmal Gokuldas Waykole, Tempe, AZ (US)

(21) Appl. No.: 19/635,924

(22) Filed: Apr. 1, 2026

Related U.S. Application Data
(60) Provisional application No. 63/783,669, filed on Apr. 4, 2025.

(51) Int. Cl. C23C 16/44; C23C 16/455

(52) U.S. Cl. CPC C23C 16/4411; C23C 16/4412; C23C 16/45544

(57) ABSTRACT

A system is provided including a main cabinet having a process chamber and a gas box disposed therein, first scrubber, disposed outside the main cabinet, in fluid communication with the gas box, a conduit disposed in the main cabinet configured to place an interior of the main cabinet in fluid communication with a fan.

### CROSS-REFERENCE TO RELATED APPLICATIONS

This application is a nonprovisional of, and claims priority to and the benefit of, U.S. Provisional Patent Application No. 63/783,669, filed Apr. 4, 2025 and entitled “HEAT MANAGEMENT SYSTEMS AND METHODS,” which is hereby incorporated by reference herein.

### FIELD

The present disclosure generally relates to heat management systems and components thereof. More particularly, the disclosure relates to systems and methods for effective heat management of gas-phase reactors and/or components thereof.

### BACKGROUND OF THE DISCLOSURE

Gas-phase reactors can be used for a variety of applications, such as chemical vapor deposition (CVD), plasma-enhanced CVD (PECVD), atomic layer deposition (ALD), plasma-enhanced ALD (PEALD), substrate precleaning, etch processes, and the like. For example, gas-phase reactors can be used to deposit material, etch layers, and/or clean material on a substrate to form electronic devices, such as semiconductor devices, flat panel display devices, photovoltaic devices, microelectromechanical systems (MEMS), and the like.

A typical gas-phase reactor system includes one or more reactors, each reactor including a reaction chamber and one or more gas sources fluidly coupled to the reaction chamber. In many applications, such as ALD, PEALD, and other cyclical processes, precursor gases flow through various components and passageways. Certain process gases contain materials that should not be emitted to the ambient atmosphere without undergoing an environmental mitigation process. Further, various components benefit from being air cooled to maintain a desired temperature yet such cooling air need not necessarily undergo an environmental mitigation process prior to being released into the ambient environment. Conventional systems may be configured to mix gases that would benefit from an environmental mitigation process with gases that would not and subject both gases to the environmental mitigation process. In that regard, additional time and expense is incurred by subjecting gases to the environmental mitigation process that do not need such treatment.

Any discussion, including discussion of problems and solutions, set forth in this section has been included in this disclosure solely for the purpose of providing a context for the present disclosure. Such discussion should not be taken as an admission that any or all of the information was known at the time the invention was made or otherwise constitutes prior art.

### SUMMARY OF THE DISCLOSURE

Various embodiments of the present disclosure relate to a system comprising a main cabinet having a process chamber and a gas box disposed therein, a first scrubber, disposed outside the main cabinet, in fluid communication with the gas box, a conduit disposed in the main cabinet configured to place an interior of the main cabinet in fluid communication with a fan.

In various embodiments, a precursor vessel disposed within the main cabinet and a second scrubber, disposed outside the main cabinet, in fluid communication with the precursor vessel.

In various embodiments, the system further comprises a second conduit placing the process chamber in fluid communication with a pump, the pump disposed outside the main cabinet, and a pressure relief valve in fluid communication with the second conduit.

In various embodiments, the pressure relief valve is in fluid communication with the gas box.

In various embodiments, the fan is configured to be in fluid communication with at least one of ambient environment or an interior of a building.

In various embodiments, the system further comprises a third conduit placing the process chamber in fluid communication with the gas box and a pressure sensor disposed in fluid communication with the third conduit.

In various embodiments, the third conduit is configured to deliver a gas to the process chamber at a pressure of less than 101.3 kPa.

In various embodiments, the pressure sensor is associated with a temperature sensor.

In various embodiments, the fan is rated to at least 15 m3/min.

In various embodiments, the system further comprises a gas detector disposed within the main cabinet and configured to detect the presence of at least one of H₂, NF₃, SiH₄, NH₃, or Mo.

In various embodiments, the system further comprises a heat exchanger in fluid communication with the fan.

Various embodiments include a system comprising a main cabinet having a process chamber and a gas box disposed therein, a conduit disposed at a base of the main cabinet and configured to place an interior of the main cabinet in fluid communication with a fan, a second conduit placing the gas box in fluid communication with the process chamber, and a pressure sensor in fluid communication with the gas box and configured to determine a pressure inside second conduit.

In various embodiments, the pressure is configured to be less than 101.3 kPa.

In various embodiments, the system further comprises a precursor vessel disposed within the main cabinet.

In various embodiments, the system further comprises a second scrubber, disposed outside the main cabinet, in fluid communication with the precursor vessel.

In various embodiments, the fan is rated to at least 15 m³/min.

Various embodiments include a method comprising disposing a process chamber and a gas box within a main cabinet, disposing a first scrubber outside the main cabinet, placing the first scrubber in fluid communication with the gas box, and placing the main cabinet in fluid communication with a fan via a conduit disposed at a base of the main cabinet.

In various embodiments, the method further comprises disposing a pressure sensor on a second conduit, the second conduit in fluid communication with both the process chamber and the gas box.

In various embodiments, the method further comprises disposing a pressure release valve on a third conduit, the third conduit in fluid communication with both the process chamber and the gas box.

In various embodiments, the method further comprises placing the fan in fluid communication with at least one of ambient environment or an interior of a building.

These and other embodiments will become readily apparent to those skilled in the art from the following detailed description of certain embodiments having reference to the attached figures. The invention is not limited to any particular embodiment(s) disclosed.

### BRIEF DESCRIPTION OF THE DRAWING FIGURES

A more complete understanding of exemplary embodiments of the present disclosure can be derived by referring to the detailed description and claims when considered in connection with the following illustrative figures.

FIG. 1 illustrates a system according to various embodiments of the present disclosure.

FIG. 2 illustrates a system structure according to various embodiments of the present disclosure.

FIG. 3 illustrates an exemplary reactor system according to various embodiments of the present disclosure.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION

Although certain embodiments and examples are disclosed below, it will be understood that the invention extends beyond the specifically disclosed embodiments and/or uses of the invention and obvious modifications and equivalents thereof. Thus, it is intended that the scope of the invention disclosed should not be limited by the particular disclosed embodiments described below.

The present disclosure generally relates to systems and methods for dosing during a gas phase reaction process such as, for example, an atomic layer deposition (ALD) process, or other cyclical deposition process, though in various embodiments may find usefulness in a number of processes, including CVD, plasma-enhanced processes, etch processes, clean processes, and the like.

As used herein, the term substrate may refer to any underlying material or materials, including and/or upon which material can be deposited. A substrate can include a bulk material, such as silicon (e.g., single-crystal silicon), other Group IV materials, such as germanium, or compound semiconductor materials, such as GaAs, and can include one or more layers overlying or underlying the bulk material. For example, a substrate can include a patterning stack of several layers overlying bulk material. The patterning stack can vary according to application. Further, the substrate can include various gaps, such as recesses, vias, spaces between lines, trenches, and the like formed on the surface of the substrate.

In this disclosure, gas can include material that is a gas at normal temperature and pressure (NTP), a vaporized solid and/or a vaporized liquid, and can be constituted by a single gas or a mixture of gases, depending on the context. A gas other than a process gas, i.e., a gas introduced without passing through a gas distribution assembly, other gas distribution device, or the like, can be used for, e.g., sealing the reaction space, and can include a seal gas, such as a rare gas. In that regard, a chemically inert gas may be flowed through the reaction chamber along with a process gas, i.e., a precursor containing gas. As used herein, “inert gas” may refer to a chemically inert gas such as the noble gases, or a relatively inert gas, such as nitrogen gas (N₂).

In this disclosure, any two numbers of a variable can constitute a workable range of the variable, and any ranges indicated may include or exclude the endpoints. Additionally, any values of variables indicated (regardless of whether they are indicated with about or not) may refer to precise values or approximate values and include equivalents, and may refer to average, median, representative, majority, or the like, in various embodiments. For example, the term about can refer to +/'20, 10, 5, 2, or 1 percent of a value. Further, in this disclosure, the terms including, comprising, constituted by and having and their equivalents can refer independently to typically or broadly comprising, consisting essentially of, or consisting of in some embodiments. In accordance with aspects of the disclosure, any defined meanings of terms do not necessarily exclude ordinary and customary meanings of the terms.

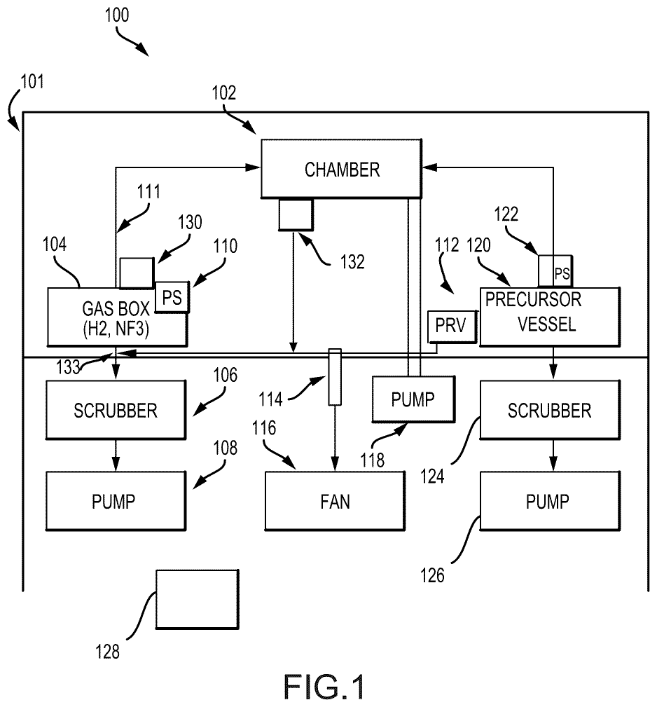

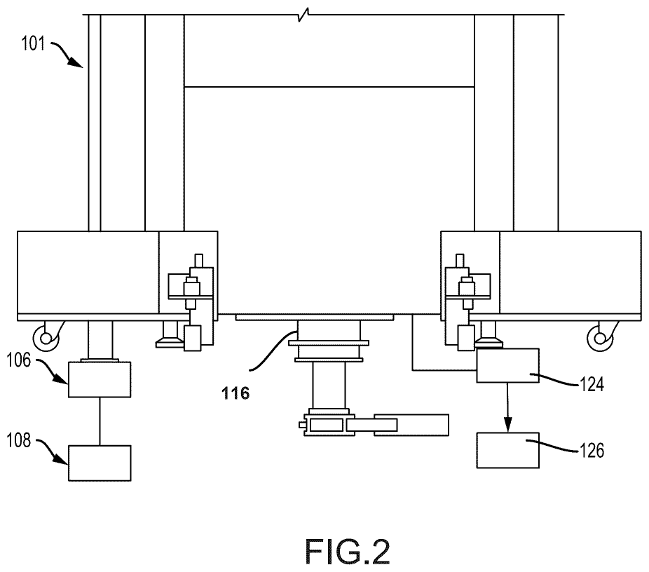

Turning now to the figures, FIGS. 1 and 2 illustrate a system 100 in accordance with at least one embodiment of the disclosure. Main cabinet 101 at least partially encloses gas box 104, reaction chamber 102, and precursor vessel 120. As gas box 104, reaction chamber 102, and precursor vessel 120 emit heat during use, main cabinet 101 acts to contain such heat. However, it is detrimental for the temperature of main cabinet 101 to rise above a predetermined temperature. Thus, removing heat from the interior volume of main cabinet to stabilize and otherwise modulate the interior temperature of main cabinet 101 is beneficial. Main cabinet 101 may be air cooled in that air from the internal volume of main cabinet 101 may be drawn out main cabinet 101. Though precursor gas may contain potentially hazardous and/or toxic materials (such as gaseous phase metals or other environmentally detrimental materials), the interior volume of main cabinet 101, when operated in accordance with various embodiments described herein, need not contain potentially hazardous and/or toxic materials. Thus, in accordance with various embodiments, air drawn from main cabinet 101 for cooling purposes need not be subject to an environmental mitigation process such as being processed through a scrubber. In this manner, only gas from gas box 104 and precursor vessel 120 would be in fluid communication with one or more scrubbers. This allows the implementation of smaller scrubbers (i.e., scrubbers that process air at a lower mass flow rate), which reduces costs (such as operation costs) over time.

Gas box 104 is configured to hold various gases, such as H₂, NF₃, SiH₄, or NH₃, among others. Gas box 104 is fluidly coupled to reaction chamber 102 to supply various gases to reaction chamber 102. Gas box 104 is also fluidly coupled to the scrubber 106 via exhaust conduit 133. Gas from gas box 104 may be supplied to scrubber 106. Scrubber 106 may then perform an environmental mitigation process on gases it receives. Scrubber 106 may be fluidly driven by pump 108. Pressure sensor 110 monitors the pressure of the conduit 111, which fluidly couples gas box 104 to reaction chamber 102. Pressure sensor 110 may be in electronic communication with controller 128. Gas box 104 comprises gas detector 130. Gas detector 130 comprises a sensor configured to detect the presence and/or concentration of one or more materials in the gaseous phase in gas box 104. Gas detector 130 may detect the presence and/or concentration of H₂, NF₃, SiH₄, NH₃, and/or Mo, among others. Gas detector 130 is in electronic communication with controller 128. In that regard, controller 128 may receive a signal indicative of a presence and/or concentration of a predetermined gas in gas box 104. Responsive to this signal, controller 128 may control the fluid control from gas box 104 to scrubber 106 via, for example, actuating a valve or other device to cause fluid communication between scrubber 106 and gas box 104.

Precursor vessel 120 is in fluid communication with reaction chamber 102 and configured to supply precursor gases to reaction chamber 102. Precursor vessel 120 may comprise various precursors in solid and or liquid form and may be configured to manipulate temperature and pressure such that the precursor materials are brought into the gaseous phase. In that regard, solid precursor material may sublimate and liquid precursor material may otherwise be brought to the gaseous phase. Pressure sensor 122 is configured to monitor the pressure inside precursor vessel 120. Gas from precursor vessel 120 may be supplied to scrubber 124. Scrubber 124 may then perform an environmental mitigation process on gases it receives. Scrubber 124 may be fluidly driven by pump 126. Pressure sensor at 122 may be in electronic communication with controller 128. The scrubber 124 may be configured to connect to a bottom of the reaction chamber 102.

Scrubber 106 and scrubber 124 may comprise any suitable air scrubbing device. For example, scrubber 106 and scrubber 124 may comprise one or more of a wet scrubber, a dry scrubber, an electrostatic precipitator scrubber, a venturi scrubber, and/or a packed bed scrubber.

Reaction chamber 102 is in fluid communication with pump 118. Pressure release valve 112 is connected to precursor vessel 120. Pressure release valve 112 is configured to remain closed unless and until a predetermined threshold pressure is reached. In response to the predetermined threshold pressure being reached, pressure release valve 112 opens to allow fluid flow into gas box 104. Pressure release valve 112 may be a mechanical assembly and or may be electronically actuated. In embodiments where pressure release valve 112 is electronically actuated, the electronic actuation apparatus that controls pressure release valve 112 is an electronic communication with controller 128. Controller 128 is able to control actuation of pressure release valve 112.

Conduit 114 is disposed in main cabinet 101 and is in fluid communication with the interior volume of main cabinet 101. Conduit 114 may comprise a pipe, tube, or other structure that enables fluid communication between the interior volume of main cabinet 101 and the exterior of main cabinet 101. Fan 116 is in fluid communication with conduit 114. Fan 116 is configured to remove air from main cabinet 101 via conduit 114 and conduct that air to another environment. The other environment may be another part of the building in which system 100 is housed (i.e., an interior of a building) or it may be to the exterior environment. Fan 116 is sized and configured to remove air from main cabinet 101 at a rate sufficient to maintain the interior of main cabinet 101 at a desired temperature or within a range of predetermined desired temperatures. In various embodiments, main cabinet 101 has a predetermined desired temperature range that allows system 100 to operate effectively. In various embodiments, fan 116 is configured to provide air movement at least from between 3 m³/min to 30 m³/min, from 5 m³/min to 20 m³/min, from 10 m³/min to 18 m³/min, or at 15 m³/min.

As discussed above, it is important that the air within the interior volume of main cabinet 101 remains free or substantially free from precursor gas and/or gases from gas box 104 because the air from main cabinet 101 is not intended to undergo an environmental mitigation process prior to release to another environment. In that regard, several techniques may be used to prevent escape from unwanted gases from entering an interior volume of main cabinet 101. For example, in various embodiments, the supply of precursor gas from precursor vessel 120 to reaction chamber 102 is provided at a pressure less than standard atmospheric pressure. Standard atmospheric pressure is generally accepted to be 101.3 kPa.

Further, pressure sensor 110 monitors the pressure in conduit 111 and may transmit a signal indicative of that pressure to controller 128. Controller 128 may be configured with a predetermined threshold pressure above which would benefit from mitigation procedures. As referenced above, pressure in conduit 111 should be kept below standard atmospheric pressure (101.3 kPa) to prevent leakage into the interior volume of main cabinet 101. In that regard, should controller 128 receive information indicative of pressure in conduit 111 exceeding 101.3 kPa, controller 128 may initiate a mitigation process. For example, controller 128 may command actuation or closure of one or more valve to gas box 104 to reduce or cease gas release into conduit 111.

Pressure release valve 132 is in fluid communication with reaction chamber 102. In that regard, pressure release valve 132 may be configured so that if the pressure within reaction chamber 102 rises above 101.3kPa, or other predetermined pressure value, pressure release valve 132 at least partially opens and allows fluid communication between pressure release valve 132 and the exhaust conduit 133, which fluidly couples gas box 104 to scrubber 106. As gas box 104 is fluidly coupled to scrubber 106 via exhaust conduit 133, gas from reaction chamber 102 is conducted to scrubber 106 without entering the interior volume of main cabinet 101. Pressure release valve 132 may be a mechanical pressure release valve. In that regard, pressure release valve 132 may comprise a compressed spring holding a poppet or ball bearing against a valve seat. The spring may be configured to be overcome after experiencing a given pressure. In various embodiments, pressure release valve 132 is electromechanically controlled. A pressure sensor may monitor the pressure in reaction chamber 102 and transmit a signal indicative of this pressure to controller 128. Controller 128 is configured to command pressure release valve 132 to open in response to receiving a signal indicative of a pressure within reaction chamber 102 that is over a predetermined threshold limit.

Moreover, pressure release valve 112 is in fluid communication with precursor vessel 120. In that regard, pressure release valve 112 may be configured so that if the pressure within precursor vessel 120 rises above 101.3kPa, or other predetermined pressure value, pressure release valve 112 at least partially opens and allows fluid communication between pressure release valve 112 and exhaust conduit 133. As gas box 104 is fluidly coupled to scrubber 106, precursor gas from precursor vessel 120 is conducted to scrubber 106 without entering the interior volume of main cabinet 101. Pressure release valve 112 may be a mechanical pressure release valve. In that regard, pressure release valve 112 may comprise a compressed spring holding a poppet or ball bearing against a valve seat. The spring may be configured to be overcome after experiencing a given pressure. In various embodiments, pressure release valve 112 is electromechanically controlled. Pressure sensor 122 may monitor the pressure in precursor vessel 120 and transmit a signal indicative of this pressure to controller 128. Controller 128 is configured to command pressure release valve 112 to open in response to receiving a signal indicative of a pressure within precursor vessel 120 that is over a predetermined threshold limit.

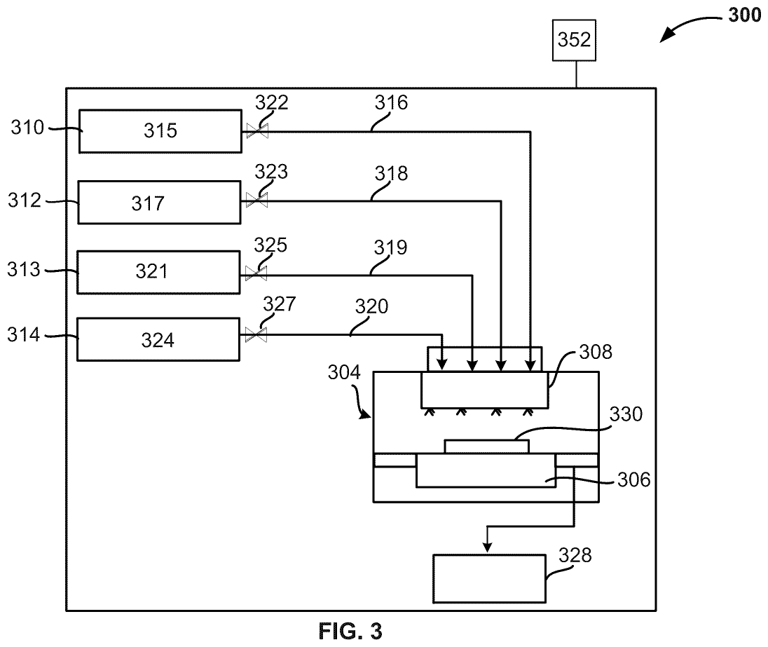

Turning now to FIG. 3, a gas flow system as disclosed herein may be used in connection with various reactor systems, for example, exemplary reactor system 300. Reactor system 300 includes a reaction chamber 304, a susceptor 306 to hold a substrate 330 during processing, a gas distribution system 308 (e.g., a showerhead) to distribute one or more precursors and/or reactants to a surface of substrate 330, one or more precursor or reactant sources 310, 312, and/or 313, and/or a carrier and/or purge gas source 314, fluidly coupled to reaction chamber 304 via respective lines 316, 318, 319 and 320, and respective valves or controllers 322, 323, 325 and 327. Substrate 330 can include a substrate as described herein. A purge/carrier gas 324 from gas source 314 can be flowed to and through reaction chamber 304 to act as a carrier gas, and/or purge or remove any excess precursor, reactant or other undesired materials from reaction chamber 304. Sources 310, 312, and 313 can include vessels and a precursor or a reactant as described herein. For example, source 310 can include a vessel and a reactant 315; source 312 can include a vessel and precursor 317; source 313 can include a vessel and another reactant 321. Reactor system 300 can include additional sources. System 300 can also include a vacuum source 328 fluidly coupled to the reaction chamber 304. Vacuum source 328 can be configured to evacuate blocking molecules, precursors, reactants, a purge gas, byproducts, or other materials out of reaction chamber 304.

Reactor system 300 also includes a controller 352. Controller 352 can be configured to perform various functions and/or steps as described herein. Controller 352 can include one or more microprocessors, memory elements, and/or switching elements to perform the various functions. Although illustrated as a single unit, controller 352 can alternatively comprise multiple devices. Controller 352 can be used to control gas flow (e.g., by monitoring flow rates and controlling valves 322, 323, 325 and/or 327), motors, heaters, cooling devices and/or vacuum source 328 to execute various processes. Further, when a system includes two or more reaction chambers, the two or more reaction chambers can be coupled to the same/shared controller. Reactor system 300 may utilize system 100 in various configurations, as will be apparent to one having ordinary skill in the art.

As noted above, example embodiments of the disclosure described above do not limit the scope of the invention, since these embodiments are merely examples of the embodiments of the invention. Indeed, various modifications of the disclosure, in addition to those shown and described herein, such as alternative useful combinations of the elements described, may become apparent to those skilled in the art from the description.

1. A system comprising:
a main cabinet having a process chamber and a gas box disposed therein;
a first scrubber, disposed outside the main cabinet, in fluid communication with the gas box; and
a conduit disposed in the main cabinet configured to place an interior of the main cabinet in fluid communication with a fan.

2. The system of claim 1, further comprising a precursor vessel disposed within the main cabinet and a second scrubber, disposed outside the main cabinet, in fluid communication with the precursor vessel.

3. The system of claim 2, further comprising a second conduit placing the process chamber in fluid communication with a pump, the pump disposed outside the main cabinet, and a pressure relief valve in fluid communication with the second conduit.

4. The system of claim 3, wherein the pressure relief valve is in fluid communication with the gas box.

5. The system of claim 4, wherein the fan is configured to be in fluid communication with at least one of ambient environment or an interior of a building.

6. The system of claim 5, further comprising a third conduit placing the process chamber in fluid communication with the gas box and a pressure sensor disposed in fluid communication with the third conduit.

7. The system of claim 6, wherein the third conduit is configured to deliver a gas to the process chamber at a pressure of less than 101.3 kPa.

8. The system of claim 7, wherein the pressure sensor is associated with a temperature sensor.

9. The system of claim 8, wherein the fan is rated to at least 15 m³/min.

10. The system of claim 9, further comprising a gas detector disposed within the main cabinet and configured to detect the presence of at least one of H₂, NF₃, SiH₄, NH₃, or Mo.

11. The system of claim 9, further comprising a heat exchanger in fluid communication with the fan.

12. A system comprising:
a main cabinet having a process chamber and a gas box disposed therein;
a conduit disposed at a base of the main cabinet and configured to place an interior of the main cabinet in fluid communication with a fan;
a second conduit placing the gas box in fluid communication with the process chamber; and
a pressure sensor in fluid communication with the gas box and configured to determine a pressure inside second conduit.

13. The system of claim 12, wherein the pressure is configured to be less than 101.3 kPa.

14. The system of claim 13, further comprising a precursor vessel disposed within the main cabinet.

15. The system of claim 14, further comprising a second scrubber, disposed outside the main cabinet, in fluid communication with the precursor vessel.

16. The system of claim 15, wherein the fan is rated to at least 15 m³/min.

17. A method comprising:
disposing a process chamber and a gas box within a main cabinet;
disposing a first scrubber outside the main cabinet;
placing the first scrubber in fluid communication with the gas box;
placing the main cabinet in fluid communication with a fan via a conduit disposed at a base of the main cabinet.

18. The method of claim 17, further comprising disposing a pressure sensor on a second conduit, the second conduit in fluid communication with both the process chamber and the gas box.

19. The method of claim 18, further comprising disposing a pressure release valve on a third conduit, the third conduit in fluid communication with both the process chamber and the gas box.

20. The method of claim 19, further comprising placing the fan in fluid communication with at least one of ambient environment or an interior of a building.
